(19) United States
(12) Patent Application Publication
(10) Pub. No.: US 2026/0221839 A1
(43) Pub. Date: Jul. 30, 2026

(54) POWER ELECTRONICS UNIT, ELECTRIC DRIVE MACHINE, AND ELECTRIC DRIVE TRAIN

(71) Applicant: Schaeffler Technologies AG & Co. KG, Herzogenaurach (DE)

(72) Inventors: Thorsten Rittgerott, Offenburg (DE); Markus Walter, Nürnberg (DE); Thorsten Biermann, Wachenroth (DE); Sebastian Jackstädt, Hilden (DE); Nicolai Gramann, Renchen (DE); Martin Klein, Scheinfeld (DE); Inaki Fernandez, Nürnberg (DE); Cornelia Smetan, Attenkirchen (DE); Götz Rathke, Hohberg (DE); Eduard Enderle, Gengenbach (DE); Sören Seliger, Altdorf b. Nürnberg (DE)

(21) Appl. No.: 19/141,611

(22) PCT Filed: Sep. 27, 2023
(86) PCT No.: PCT/DE2023/100719

§ 371 Date: Jun. 20, 2025

(30) Foreign Application Priority Data
Dec. 20, 2022 (DE) 102022134032.5

(51) Int. Cl. H02K 5/22; F15B 15/18; H02K 11/33

(52) U.S. Cl. CPC H02K 5/225; F15B 15/18; H02K 11/33

(57) ABSTRACT

The present invention relates to a power electronics unit (1) for controlling an electric drive machine (2), with an inverter (5) arranged in a housing (3) for actuating a hydraulic pump (4), wherein at least a first electrical plug connector (6) and a second electrical plug connector (7) are formed between the inverter (5) and the hydraulic pump (4). The first electrical plug connector (6) and the second electrical plug connector (7) have a common central fixing point (8a) on an inner side (9) of the housing (3). Furthermore, the present invention relates to an electric drive machine (2) and an electric drive train (14).

### CROSS-REFERENCE TO RELATED APPLICATION

The present application is the U.S. National Phase of PCT Patent Application Number PCT/DE2023/100719, filed on Sep. 27, 2023, which claims priority to German Patent Application Number 10 2022 134 032.5, filed Dec. 20, 2022, the entire disclosures of which are incorporated by reference herein.

### TECHNICAL FIELD

The present disclosure relates to a power electronics unit for controlling an electric drive machine, an electric drive machine, and an electric drive train.

### BACKGROUND

Electric drive trains for powering vehicles are widely used in the prior art. Such an electric drive train usually contains an electric drive machine, for example in the form of an electric motor consisting of a stator and a rotor, a hydraulic circuit with a hydraulic pump, and a power electronics unit for controlling the electric motor and the hydraulic pump.

In such electric drive trains, the power electronics unit and the hydraulic pump can be designed to be separated from one another so that an oil-tight electric interface/connection between the power electronics and the hydraulic pump is required. Such electric interfaces include a signal part and a power part, which can be designed as two separate plugs or as a combined plug.

Two separate plugs have the disadvantage of requiring a lot of installation space and increasing the installation effort. A combined plug has the disadvantage that it is usually a custom-made product, which is expensive and not compatible with standard connections.

### SUMMARY

The object of the present disclosure is to eliminate or at least mitigate the disadvantages of the prior art.

This object is achieved by a power electronics unit according to claim 1, an electric drive machine and an electric drive train according to one of the independent claims. Advantageous further developments of the disclosure are described in the dependent claims and below.

Specifically, the object is achieved by the power electronics unit for controlling an electric drive machine, with an inverter arranged in a housing for controlling a hydraulic pump, wherein at least a first electric plug connector and a second electric plug connector are formed between the inverter and the hydraulic pump. The first electric plug connector and the second electric plug connector have a common central fixing point on an inner side of the housing.

In other words, the object is achieved by the power electronics unit, which is designed to control the electric drive machine. The power electronics unit contains the housing in which the inverter is arranged, wherein the inverter is intended and designed to control the hydraulic pump. The power electronics unit further contains the first electric plug connector and the second electric plug connector, via which the power electronics unit can be connected directly or indirectly to the hydraulic pump. The first electric plug connector and the second electric plug connector pass through the housing of the power electronics unit and are connected to the housing at least at the central fixing point on the inner side of the housing preferably in a form-fitting manner. In still other words, the first electric plug connector and the second electric plug connector are fixed together at the central fixing point by a single fixing means. In other words, the central fixing point is doubly occupied by the first electric plug connector and the second electric plug connector.

The core of the disclosure is thus that both the first electric plug connector and the second electric plug connector have at least one fixing section, for example in the form of a hole, and the fixing section of the first electric plug connector and of the second electric plug connector overlap or coincide at least at the common central fixing point.

By designing a common central fixing point in this manner, the first electric plug connector and the second electric plug connector can be positioned close together in a space-efficient manner. In addition, the common central fixing point simplifies the assembly.

In a first aspect, the first electric plug connector can be fixed at exactly two fixing points on the housing, wherein one of the fixing points is the central fixing point, and the second electric plug connector can be fixed at exactly two fixing points on the housing, wherein one of the fixing points is the central fixing point.

In other words, the first electric plug connector and the second electric plug connector can be fixed on the housing at a total of exactly three fixing points, wherein one of the fixing points is the central fixing point used by both the first electric plug connector and the second electric plug connector.

In other words, both the first electric plug connector and the second electric plug connector can each be fixed on the housing of the power electronics unit with an individual fixing point specific to the plug connector as well as with the common central fixing point. By designing the fixing points in this manner, an optimal compromise between redundant fixing, positioning and installation space utilization in the power electronics unit can be achieved.

In a further aspect, all fixing points of the first electric plug connector and the second electric plug connector can be arranged on a straight line.

In other words, the first electric plug connector and the second electric plug connector can be formed directly adjacent to one another in an aligned orientation next to one another in the housing of the power electronics unit. In this way, the most compact possible design of the power electronics unit can be achieved.

In a further aspect, the central fixing point can be designed as a threaded rod formed on or in the housing.

In other words, the fixing means formed at the central fixing point can be a threaded rod, preferably connected in a non-detachable manner to the housing, onto which the first electric plug connector and the second electric plug connector are pushed with their respective fixing section during assembly and are then fixed with a further associated fixing means, for example a nut, in a form-fitting manner. By designing the common central fixing point as a threaded rod, the assembly can be made considerably easier for a person carrying out the assembly, as he can slide both the first electric plug connector and the second electric plug connector onto the threaded rod in order to then fix the first electric plug connector and the second electric plug connector at the individual fixing points. The common central fixing point therefore acts as an assembly aid in this type of design.

Preferably, the first electric plug connector can be a signal plug.

Further preferably, the second electric plug connector can be a three-phase plug.

In other words, the signal plug/a signal interface and the three-phase plug/a power interface can be formed separately from one another. In particular, at least one of the signal plug and the three-phase plug can be a purchased part or a standardized component. In this way, compatibility with standard components can be achieved with a compact design, which contributes to a considerable reduction in costs.

In a further aspect, the first electric plug connector and the second electric plug connector can each be formed with a seal on an outer side of the housing.

In other words, both the first electric plug connector and the second electric plug connector can be sealed/sealable radially with a seal on a section arranged on the outer side of the housing so that penetration of a medium, for example a hydraulic oil, into the power electronics unit via the first or the second electric plug connector can be prevented.

Preferably, the first electric plug connector can be sealed with a flat seal.

Furthermore, the second electric plug connector can preferably be sealed with an O-ring.

Of course, all other suitable seal shapes/types are also feasible. In particular, the seal can be designed as an oil-resistant seal so that swelling of the seal can be prevented.

In a further aspect, the second electric plug connector can extend further in a direction normal to the outer side of the housing away from the outer side of the housing than the first electric plug connector.

In other words, the second electric plug connector can be designed as a male plug connector which extends away from the outer side of the housing. In this way, the second electric plug connector can act as a guide element during assembly so that the more sensitive first electric plug connector or one with finer contacts can/will be correctly positioned by the inserted second electric plug connector and damage to the first electric plug connector can be prevented.

The object of the present disclosure is further achieved by an electric drive machine having a power electronics unit used to control a stator or rotor according to one of the above aspects.

In other words, the electric drive machine contains at least the stator and the rotor and the power electronics unit. The power electronics unit is intended and designed to control the stator or the rotor for driving a motor vehicle.

Furthermore, the object of the present disclosure is achieved by an electric drive train having an electric drive machine according to the above aspect and a hydraulic circuit which contains at least one hydraulic pump controllable by a power electronics unit.

In other words, in addition to the electric drive machine, the electric drive train contains the hydraulic circuit and a hydraulic pump integrated into the hydraulic circuit. The hydraulic circuit can, for example, be intended and designed to lubricate and/or cool the electric drive train. The hydraulic pump is controlled by the power electronics unit.

### BRIEF DESCRIPTION OF THE DRAWINGS

Brief description of the figures

FIG. 1 is a representation of the inner side of a power electronics unit according to the disclosure;

FIG. 2 is a representation of an outer side of the power electronics unit according to the disclosure; and

FIG. 3 shows a schematic structure of a drive train according to the disclosure.

### DETAILED DESCRIPTION

Exemplary embodiments of the present disclosure are described below on the basis of the accompanying figures.

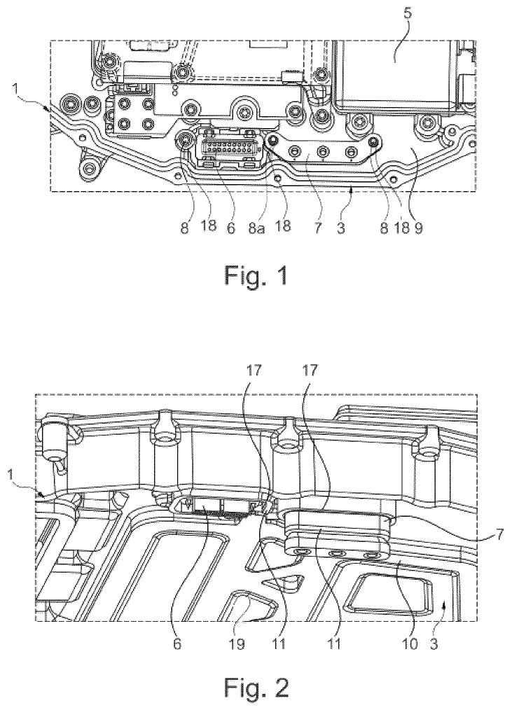

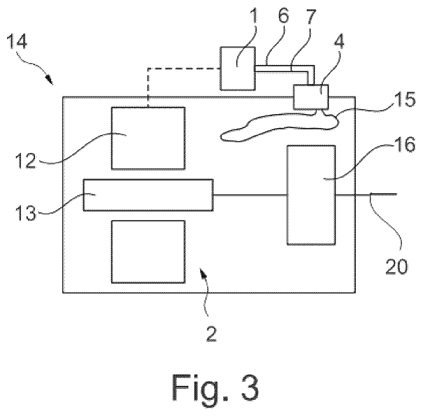

FIG. 1 shows an inside view of a power electronics unit 1 according to the disclosure for controlling an electric drive machine 2 (see FIG. 3), with an inverter 5 arranged in a housing 3 for controlling a hydraulic pump 4. At least a first electric plug connector 6, which is designed as a multi-pin signal plug, and a second electric plug connector 7, which is designed as a three-pin plug or a power plug, are arranged between the inverter 5 and the hydraulic pump 4. The housing 3 is designed as a multi-part housing 3, wherein only one half of the housing is shown in FIG. 1 and FIG. 2. The housing 3 or the housing half can be designed as a formed sheet metal part or a cast part. The first electric plug connector 6 and the second electric plug connector 7 pass through the housing 3 in recesses 17 provided for this purpose in the housing 3. A housing seal (not shown) is formed between the recess 17 and the first electric plug connector 6 or the second electric plug connector 7.

The first electric plug connector 6 and the second electric plug connector 7 are fixed directly adjacent to one another on an inner side 9 of the housing 3 in a form-fitting manner and have a common central fixing point 8a on an inner side 9 of the housing 3. For this purpose, both the first electric plug connector 6 and the second electric plug connector 7 each contain two fixing openings 18. In the exemplary embodiment shown here, the central fixing point 8a is designed as a threaded rod and receives one fixing opening 18 each of the first electric plug connector 6 and the second electric plug connector 7. In addition to the central fixing point 8a, the first electric plug connector 6 is also mounted on the housing 3 by means of a screw at a further fixing point 8. In addition to the central fixing point 8a, the second electric plug connector 7 is also mounted to another of the fixing points 8 by means of a threaded rod. At the central fixing point 8a, the fixing openings 18 of the first electric plug connector 6 and the second electric plug connector 7 coincide or overlap. All fixing points 8, 8a are arranged on a straight line or in a row next to one another.

FIG. 2 shows an outside view of the power electronics unit 1 according to the disclosure. The first electric plug connector 6 and the second electric plug connector 7 are each formed with a circumferential seal 11 on an outer side of the housing 10, which protects the first electric plug connector 6 and the second electric plug connector 7 against the ingress of media, for example hydraulic oil, in a mounted state of the power electronics unit 1. The second electric plug connector 7 extends further away from the outer side of the housing 10 than the first electric plug connector 6. In the exemplary embodiment shown here, the outer side of the housing 10 is reinforced with a large number of corrugations 19.

FIG. 3 shows a schematic structure of an electric drive train 14 according to the disclosure. The power electronics unit 1 controls the electric drive machine 2. Specifically, the power electronics 1 controls a stator 12 or rotor 13 of the electric drive machine 2. The rotor 13 is connected to a transmission 16, which outputs a drive force via an output shaft 20.

The power electronics unit 1 is furthermore connected to the hydraulic pump 4 via the first electric plug connector 6 and the second electric plug connector 7 and controls the hydraulic pump 4, which is integrated into a hydraulic circuit 15. The hydraulic circuit 15 is only shown schematically here and can fulfill a variety of functions, for example lubrication and cooling of the electric drive train 14.

### LIST OF REFERENCE SYMBOLS

1 Power electronics unit
2 Electric drive machine
3 Housing
4 Hydraulic pump
5 Inverter
6 First electric plug connector
7 Second electric plug connector
8 Fixing point
8a Common central fixing point
9 Inner side of the housing
10 Outer side of the housing
11 Seal
12 Stator
13 Rotor
14 Electric drive train
15 Hydraulic circuit
16 Transmission
17 Recess
18 Fixation opening
19 Corrugation
20 Output shaft

1. A power electronics unit for controlling an electric drive machine comprising:
an inverter arranged in a housing for controlling a hydraulic pump,
at least a first electric plug connector and a second electric plug connector being formed between the inverter and the hydraulic pump,
the first electric plug connector and the second electric plug connector having a common central fixing point on an inner side of the housing.

2. The power electronics unit according to claim 1, wherein the first electric plug connector is fixed at exactly two fixing points on the housing, wherein one of the fixing points is the central fixing point and the second electric plug connector is fixed at exactly two fixing points on the housing, wherein one of the fixing points is the central fixing point.

3. The power electronics unit according to claim 2, wherein all fixing points of the first electric plug connector and of the second electric plug connector are arranged on a straight line.

4. The power electronics unit according to claim 1, wherein the central fixing point is designed as a threaded rod formed on or in the housing.

5. The power electronics unit according to claim 1, wherein the first electric plug connector is a signal plug.

6. The power electronics unit according to claim 1, wherein the second electric plug connector is a three-phase plug.

7. The power electronics unit according to 1, wherein the first electric plug connector and the second electric plug connector are each formed with a seal on an outer side of the housing.

8. The power electronics unit according to claim 7, wherein the second electric plug connector extends further in a direction normal to the outer side of the housing than the first electric plug connector.

9. An electric drive machine having a power electronics unit used to control a stator or rotor according to claim 1.

10. An electric drive train having an electric drive machine according to claim and a hydraulic circuit which contains at least one hydraulic pump controllable by a power electronics unit.

11. A power electronics unit for controlling an electric drive machine comprising:
an inverter arranged in a housing for controlling a hydraulic pump; and
at least a first electric plug connector and a second electric plug connector formed between the inverter and the hydraulic pump,
the first electric plug connector and the second electric plug connector having a common central fixing point on an inner side of the housing,
the first electric plug connector being a signal plug and the second electric plug connector being a three-phase plug.

12. The power electronics unit according to claim 11, wherein the first electric plug connector is fixed at exactly two fixing points on the housing, wherein one of the fixing points is the central fixing point and the second electric plug connector is fixed at exactly two fixing points on the housing, wherein one of the fixing points is the central fixing point.

13. The power electronics unit according to claim 12, wherein all fixing points of the first electric plug connector and of the second electric plug connector are arranged on a straight line.

14. The power electronics unit according to claim 11, wherein the central fixing point is designed as a threaded rod formed on or in the housing.

15. The power electronics unit according to claim 11, wherein the first electric plug connector and the second electric plug connector are each formed with a seal on an outer side of the housing.

16. The power electronics unit according to claim 15, wherein the second electric plug connector extends further in a direction normal to the outer side of the housing than the first electric plug connector.

17. An electric drive train comprising:
an electric drive machine including a stator and a rotor connected to a transmission; and
a power electronics unit for controlling the electric drive machine, wherein the power electronics unit comprises:
an inverter arranged in a housing for controlling a hydraulic pump;
at least a first electric plug connector and a second electric plug connector formed between the inverter and the hydraulic pump,
the first electric plug connector and the second electric plug connector having a common central fixing point on an inner side of the housing.

18. The electric drive train according to claim 17, wherein the first electric plug connector is fixed at exactly two fixing points on the housing, wherein one of the fixing points is the central fixing point and the second electric plug connector is fixed at exactly two fixing points on the housing, wherein one of the fixing points is the central fixing point.

19. The electric drive train according to claim 18, wherein all fixing points of the first electric plug connector and of the second electric plug connector are arranged on a straight line.

20. The electric drive train according to claim 17, wherein the central fixing point is designed as a threaded rod formed on or in the housing.
